(19) United States
(12) Patent Application Publication
(10) Pub. No.: US 2025/0194196 A1
(43) Pub. Date: Jun. 12, 2025

(54) APPARATUSES AND METHODS INVOLVING SEMICONDUCTOR DEVICE WITH CURRENT-BLOCKING LAYER

(71) Applicant: The Board of Trustees of the Leland Stanford Junior University, Stanford, CA (US)

(72) Inventors: Ke Zeng, Stanford, CA (US); Srabanti Chowdhury, San Ramon, CA (US)

(21) Appl. No.: 18/852,395

(22) PCT Filed: Apr. 18, 2023
(86) PCT No.: PCT/US2023/018974

§ 371 Date: Sep. 27, 2024

Related U.S. Application Data
(60) Provisional application No. 63/333,902, filed on Apr. 22, 2022.

(51) Int. Cl. H10D 62/80; H01L 21/385; H10D 30/01; H10D 30/66; H10D 62/17

(52) U.S. Cl. CPC H10D 62/875; H01L 21/385; H10D 30/0291; H10D 30/66; H10D 62/393

(57) ABSTRACT

In certain examples, methods and semiconductor structures are directed to devices and methods involving a semiconductor device with a current-blocking layer (CBL) and a first material layer having n-type dopant material that is activated with recovered crystallinity. The CBL may have a surface portion along a plane of the CBL (e.g., in a transistor, the CBL may be between the first material layer and another material layer). A p-type dopant material is located or diffused into the CBL and activated without recovered crystallinity, and the CBL's dopant profile is characterized as corresponding to an outer portion of the CBL with a higher concentration of the p-type dopant material than a concentration of the p-type dopant material in an inner portion of the CBL.

### BACKGROUND

Aspects of the present disclosure are related generally to the field of efficiently-operable power electronics, and as may be exemplified by semiconductor devices and power electronic devices, for example, including materials which may operate using a large bandgap for handling higher levels of power.

An exemplary use or application of such technology for ease of discussion and to gain an understanding of applications, background efforts and the like, it has been appreciated that electrification of energy sources has become important in many sectors of daily living which require or are benefited by circuit designs which operate and/or consume power in efficient manners. Non-limiting examples in this context include electric cars and solar/wind power farms. Advancements in these exemplary contexts are poised to transform the landscape of society towards a more sustainable future, and one exemplary aspect of this process is the reduction of energy loss in the conversion of electric power used to operate such equipment.

More specifically, any modern power converters use numerous semiconductor devices such as various forms of diodes and in some instance, as transistor-based switches to modulate the form of electric power before delivering the power to the equipment. Consider, for example, power transistors inside DC to AC traction inverters of the electric vehicle drivetrain. These semiconductor switches are traditionally made with silicon. However, by replacing silicon with materials with a larger bandgap that can handle higher power, the power loss in the conversion stage can be drastically reduced while shrinking the system footprint.

Use of ultra-wide-bandgap (UWBG) semiconductor is one specific exemplary context which has been useful to a degree for improving efficiency issues in connection with such equipment. In particular, fourth-generation (UWBG, e.g., gallium oxide (GaO-type)) semiconductor beta-gallium oxide (β-Ga₂O₃) promises a significant improvement in efficiency for power electronics due to its large bandgap of 4.8 eV. This large bandgap gives rise to a high Baliga's power figure of merit (BFoM). BFoM measures how suitable a material may be for use in power devices. In addition, a mature melt-growth technology has been used for producing large-area high qualify Ga₂O₃ wafers. Compared to the high temperature and pressure vapor-phase growth required or used for SiC and GaN wafers, a Ga₂O₃ wafer can be potentially produced much less expensively, making Ga₂O₃ power devices especially cost-effective. High performance lateral Ga₂O₃ MOSFETs (Metal-Oxide-Semiconductor Field-Effect Transistor) with various architectures were demonstrated over the years. However, one drawback of Ga₂O₃ is the lack of effective p-type doping, which severely hinders the vertical Ga₂O₃ transistor development. Although first-principle simulations have predicted magnesium (Mg), zinc (Zn), and nitrogen (N) as potential p-type dopants, effective and proper p-type carrier behavior in Ga₂O₃ power devices has yet to be observed in a realistic/practicable manner, perhaps caused by the self-trapped holes and high ionization energy of the p-type dopants in Ga₂O₃.

More specifically, according to the present disclosure and in connection with example experimental embodiments, demonstrations of Ga₂O₃ vertical transistor with Mg-doped current blocking layer (CBL) by ion-implantation have shown weak gate modulation with almost no blocking behavior, and this is mainly due to the disruption of the CBL doping profile from the diffusion of Mg during the post-implantation annealing required or used for the crystal recovery and activation of the dopant. This problem has been considered difficult to resolve due to a tension or conflict between the high diffusivity of Mg in Ga₂O₃ above 900° C. and the high temperature of greater than 1000° C. typically used for crystal recovery. In conventional silicon technology, there are mainly three ways to dope: first is the widely used ion-implantation; second is in-situ growth of a doped layer which is not selective; the third method is thermal diffusion from a dopant source in close proximity to the target, which is especially popular in silicon power devices such as semiconductor devices (including, for example, a transistor or a diode) that are LDMOS (laterally diffused metal-oxide-semiconductor) and VDMOS (vertical-diffused metal-oxide-semiconductor, such as a VDMOSFET).

### SUMMARY OF VARIOUS ASPECTS AND EXAMPLES

Various aspects and examples according to the present disclosure are directed to addressing issues such as those addressed above and/or others which may become apparent from the following disclosure. For example, in connection with specific exemplary aspects, which in some specific instances may also be useful in overcoming previously-used techniques such as discussed above, diffusion doping techniques, and resulting (and/or related) devices, a p-type dopant such as by a convenient and known technique (e.g., spin-on-glass (SOG)) is used as a doping source to form a current blocking layer (CBL) which exhibits impressive attributes found to be highly beneficial in applications including but not limited to high-efficiency power conversion. As non-limiting examples relating to the present disclosure, the CBL may be part of a vertical GaO-type (gallium oxide-type) field-effect transistor.

In one specific example according to the present disclosure, devices or circuits include semiconductor device having at least two adjacent layers of opposite polarity, such as a transistor. Using a transistor as an example, the device has a first material layer with n-type dopant material that is activated with recovered crystallinity, and the CBL has a surface portion located (e.g., in some instances sandwiched along a plane of the CBL and in the example of a transistor embodiment, the CBL may be between the first material layer and another material layer). A p-type dopant material is located or diffused into the CBL and activated without recovered crystallinity, and the CBL's dopant profile is characterized as corresponding to an outer or surface portion of the CBL with a higher concentration of the p-type dopant material (e.g., in a direction parallel to the plane than a concentration of the p-type dopant material in an inner portion of the CBL).

Relating to the above type of transistor, other specific examples according to the present disclosure are directed to methods for using such devices or circuits. In such methods (and for some example devices or circuits), a first step concerns operating a semiconductor device that includes a first material layer having n-type dopant material that is activated with recovered crystallinity and that includes a current-blocking layer (CBL) having a surface portion (e.g., located along a plane of the CBL and again in a transistor, between the first material layer and a second material layer). A second step concerns using the CBL in at least one of multiple states of operating the device to block current via a p-type dopant material, located within the CBL and activated without recovered crystallinity. This p-type dopant material has a dopant profile characterized as corresponding to an outer or surface portion of the CBL with a higher concentration of the p-type dopant material (e.g., in a direction parallel to the plane than a concentration of the p-type dopant material in an inner portion of the CBL). In certain more specific examples, at least one of multiple states of operating the transistor is an offstate in which the CBL blocks current, and the step of operating the transistor may be used to facilitate signal-edge terminations for signals coupled to and effected by the (e.g., transistor) device transitioning through one or more of the multiple states.

In yet other specific examples, the present disclosure is directed to methods of manufacture involving formation of a current-blocking layer (CBL) which has a surface portion adjacent to a first material layer (e.g., along a plane of the CBL adjacent immediately adjacent or via a thin interconnecting/interface layer). The first material layer is formed to include n-type dopant material that is activated with recovered crystallinity, and the CBL is formed to include a p-type dopant material, located within the CBL and activated without recovered crystallinity, to have a dopant profile characterized as corresponding to an outer or surface portion of the CBL with a higher concentration of the p-type dopant material than a concentration of the p-type dopant material in an inner portion of the CBL.

Further, in specific instances the immediately-preceding methods may be used to form a field-effect transistor that includes each of the CBL, the first material layer and a second (other) material layer, with the CBL being sandwiched between the first material layer and the second material layer, and with the second material also being configured with n-type polarity.

The above discussion is not intended to describe each aspect, embodiment or every implementation of the present disclosure. The figures and detailed description that follow also exemplify various embodiments.

### BRIEF DESCRIPTION OF FIGURES

Various example embodiments, including experimental examples, may be more completely understood in consideration of the following detailed description in connection with the accompanying drawings, each in accordance with the present disclosure, in which:

FIGS. 1A, 1B and 1C depict a cross-section schematic view showcasing exemplary fabrication process steps of an exemplary transistor (e.g., Ga₂O₃ VDBFET), in accordance with the present disclosure, with: FIG. 1A showing post drive-in diffusion of dopants; FIG. 1B showing post-silicon ion-implantation and activation for source region, and FIG. 1C showing the final fabricated device;

FIGS. 2A, 2B and 2C show an example device (e.g., diode, pn junction and/or test structure) and its performance aspects according to the present disclosure, with FIG. 2A depicting a cross-section schematic of the device, with FIG. 2B depicting capacitance-voltage characteristics of the device, and with FIG. 2C depicting the dependence of capacitance and depletion width on the annealing temperature, also in accordance with the present disclosure;

FIGS. 3A, 3B and 3C show a certain example device and its performance aspects according to the present disclosure, wherein FIG. 3A depicts aspects of a SIMS depth profile of Si and Mg in a related n+ implanted region of a device as shown in FIG. 3B, in FIG. 3B, the surface region from 0 to 0.5 μm is dominated by the implanted Si dopant, and FIG. 3C depicts an optical image of the measuring device;

FIGS. 4A, 4B and 4C depict DC-IV characteristics of an example vertical diffused barrier field-effect-transistor (VDBFET) fabricated in accordance with the present disclosure, with FIG. 4A showing representative output (V_{ds}-I_{d}) characteristic, FIG. 4B showing transfer (V_{gs}-I_{d}) characteristic, and FIG. 4C showing transfer (V_{gs}-I_{d}) characteristic of the device; and

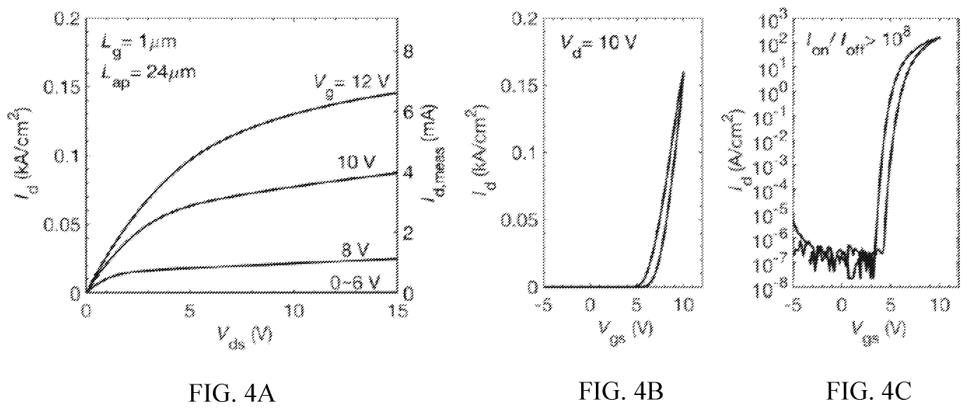

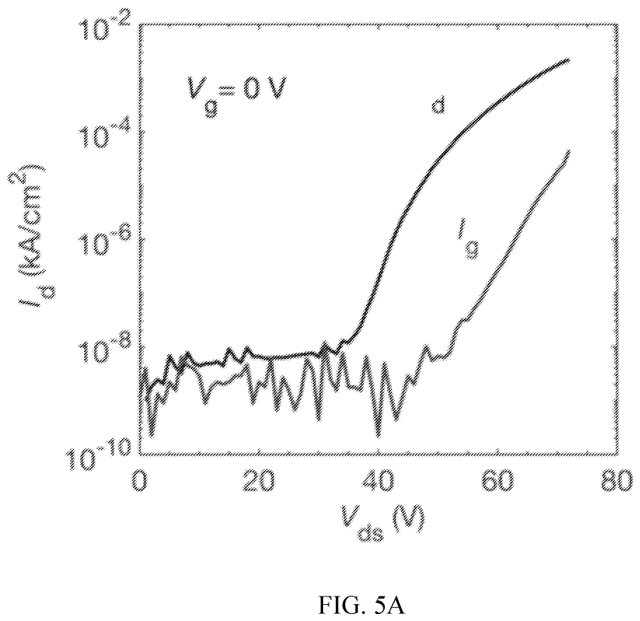

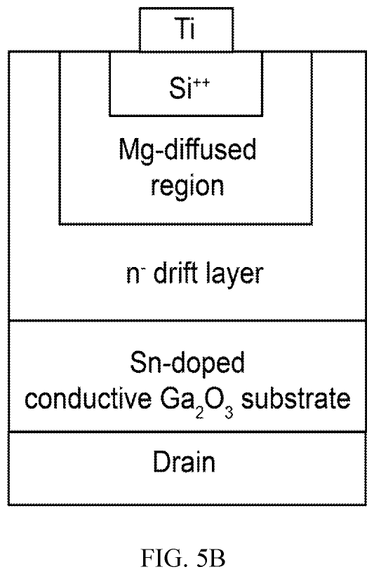

Also in accordance with the present disclosure, FIG. 5A depicts three terminal breakdown characteristic of the device of FIGS. 4A, 4B and 4C, and FIG. 5B depicts an example pn semiconductor device also including a CBL.

While various embodiments discussed herein are amenable to modifications and alternative forms, aspects thereof have been shown by way of example in the drawings and will be described in detail. It should be understood, however, that the intention is not to limit the disclosure to the particular embodiments described. On the contrary, the intention is to cover all modifications, equivalents, and alternatives falling within the scope of the disclosure including aspects defined in the claims. In addition, the term “example” as used throughout this application is only by way of illustration, and not limitation.

### DETAILED DESCRIPTION

Aspects of the present disclosure are believed to be applicable to a variety of different types of apparatuses, systems and methods involving devices characterized at least in part by use of diffusion doping in transistor devices, wherein a p-type dopant (e.g., magnesium (Mg)) is used as a doping source to form a current blocking layer adjacent an n-type or Silicon-based layer. While the present disclosure is not necessarily limited to such aspects, an understanding of specific examples in the following description may be understood from discussion in such specific contexts.

In certain example embodiments, aspects of the present disclosure involve approaches for providing an effective barrier to block current in a vertical electron device, for example, to replicate the effect of the p-type doped layer in conventional vertical power FETs, and for a wide variety of applications including those mentioned hereinabove and in connection with the citations listed in underlying U.S. Provisional Application (Ser. No. 63/333,902, filed Apr. 22, 2022, to which priority is claimed). As will become apparent, certain specific examples of the present disclosure are directed to vertical FinFETs with high BFoM in a manner which serves the growing desire for low-cost, high reliability, all-planar vertical Ga₂O₃ power devices such as FETs, especially given the availability of cost-effective native substrate capable of a higher power density due to a larger bandgap and reduced cost mainly due to ease of wafer production. Consistent with the above, such a manufactured device or method of such manufacture may involve aspects presented in the above-noted U.S. Provisional Application, and to the extent permitted, such subject matter is incorporated by reference in its entirety generally and to the extent that further aspects and examples (such as experimental and/more-detailed embodiments) may be useful to supplement and/or clarify.

In other specific aspects, the present disclosure concerns a semiconductor device that can handle much higher power than currently available semiconductor devices, so as to enable devices with high efficiency and high power and in many instances as super-compact power converters. The electrification of energy sources in every sector of typical daily lives of many, such as in uses of electric cars and solar/wind power farms, is poised to drastically transform the landscape of society towards a more sustainable future.

One aspect of this process according to the present disclosure involves one of more of the above-noted aspects for reducing energy loss in the conversion of electric power. The modern power converters use numerous semiconductor switches to modulate the form of electric power, for example, the power transistors inside the DC to AC traction inverters of the electric vehicle drivetrain. These semiconductor switches are traditionally made with silicon. However, by replacing silicon with materials with a larger bandgap that can handle higher power, like gallium oxide, in this case, the power loss in the conversion stage can be drastically reduced while shrinking the system footprint. By following certain specific aspects according to the present disclosure, significant improvements may be realized (e.g., in applications in and around the renewable energy industry) by drastically reducing the power loss everywhere and making electric-power-source charging much faster, cheaper, and accessible.

Accordingly, in the following description various specific details are set forth to describe specific examples presented herein. It should be apparent to one skilled in the art, however, that one or more other examples and/or variations of these examples may be practiced without all the specific details given below. In other instances, well known features have not been described in detail so as not to obscure the description of the examples herein. For ease of illustration, the same connotation and/or reference numerals may be used in different diagrams to refer to the same elements or additional instances of the same element. Also, although aspects and features may in some cases be described in individual figures, it will be appreciated that features from one figure or embodiment can be combined with features of another figure or embodiment even though the combination is not explicitly shown or explicitly described as a combination.

According to certain more specific examples, the present disclosure is directed to devices manufactured with a CBL as characterized with aspects disclosed herein, methods of using such a device, and methods for manufacturing a device with a CBL according to the present disclosure. For example, in specific non-limiting examples such a circuit may include or refer to an electric power converter configured to convert an input power source to a power source for a load through the use of signal modulation, and wherein the transistor is a field-effect transistor to switch or modulate one or more signals as part of the signal modulation. In one more-specific example embodiment, the transistor is a diffused-barrier-field-effect transistor which exhibits an on-off operation-switching ratio (e.g., useful for driving the modulation signal or otherwise facilitating signal switching for the modulation) which is greater than 10⁵ and in some instances greater than 10⁵, and in other instances approaching or exceeding 10⁸.

In such exemplary circuitry, the transistor may be a FET-type transistor including a channel, and the dopant profile of the CBL may be configured to facilitate an operation for the FET which corresponds to the FET being in a normally off state of operation while the channel is open. As one of many examples, such a FET-type transistor may be included as part of an UWBG semiconductor-beta-gallium oxide (β-Ga₂O₃) power-sourcing or amplification circuit, of which the transistor forms a part. In exemplary contexts, example devices in accordance with the present disclosure may include material(s) of any one or more of different bandgaps where a band gap refers to the energy required for electrons and holes to transition from the valence band to the conduction band (e.g., a WBG device refers to a semiconductor with a bandgap of larger than that of a conventional semiconductor such as Silicon).

In certain examples involving devices manufactured to include (or otherwise having) a CBL according to the present disclosure, an apparatus, system and/or circuit-based device includes a transistor with a current-blocking layer (CBL). The transistor includes a first material layer having n-type dopant material that is activated with recovered crystallinity, and the CBL may have a surface portion sandwiched between the first material layer and another material layer. A p-type dopant material is located or diffused into the CBL and activated without recovered crystallinity, and the CBL's dopant profile is characterized as corresponding to an outer or surface portion of the CBL with a higher concentration of the p-type dopant material (e.g., in a direction parallel to a plane of the surface portion and with the concentration higher than a concentration of the p-type dopant material in an inner portion of the CBL).

More specific examples relate to and/or build on the above aspects. For instance, in connection with the above circuit, a part of the surface portion of the CBL may include Silicon and/or n-type dopants immediately adjacent the first material layer. In other examples, the CBL and the first material layer may be separated by a thin interface layer which does not inhibit onstate operation of the device (e.g., by more than a negligible amount as may be apparent from current-through testing relating to specification requirements for the device). In a more specific example, such a thin interface layer may include a set of one or more atomically thin layers (e.g., a transition-metal dichalcogenide layer or contacted layers of p-type tungsten diselenide (WSe₂) and n-type molybdenum disulphide (MoS₂)). This Si-based or dopant-based inclusion may occur, for example, during processing (annealing) of a Silicon layer which may correspond to the first material layer or second material layer. Also, in an application in which the transistor if a FET, the CBL may form part of a Ga₂O₃ vertical diffused barrier field-effect-transistor (VDBFET).

In specific examples, and depending on the manufacturing process used and the design specified for the circuit, the dopant profile may be characterized as having a near-box with a linear upper part corresponding to a highest level of dopant concentration at the surface portion and with linearly-sloped sides. These aspects are discussed in more specific examples herein.

In certain examples involving methods of using such a device with a CBL according to the present disclosure, such a method may include operating a transistor that includes a first material layer having n-type dopant material that is activated with recovered crystallinity and that includes a middle current-blocking layer (CBL) having a surface portion which is sandwiched between the first material layer and a second material layer of the device. Further, the method may include using the CBL in at least one of multiple states of operating the transistor to block current via a p-type dopant material located within the CBL and activated without recovered crystallinity (e.g., typically associated with an annealing step for ion-implanted dopant). As with previous example embodiments of the present disclosure, the p-type dopant material has a dopant profile characterized as corresponding to an outer or surface portion of the CBL with a higher concentration of the p-type dopant material

In more specific exemplary uses according to the present disclosure, the method may further include operating the transistor with the CBL being used to facilitate signal-edge terminations for signals coupled to and effected by the transistor transitioning through one or more of the multiple states, and/or may further include using the transistor as to switch or to modulate one or more signals as part of the signal modulation in an electric power converter, and while using the electric power converter to convert an input power source to a power source for a load through the use of the signal switching and/or modulation.

Certain other examples according to the present disclosure involve methods for manufacturing a device with a CBL such as ones characterized hereinabove and as follows. In such specific examples, the methods of manufacture involve formation of a current-blocking layer (CBL) which has a surface portion sandwiched between a first material layer and another material layer. The first material layer is formed to include n-type dopant material that is activated with recovered crystallinity, and the CBL is formed to include a p-type dopant material, located within the CBL and activated without recovered crystallinity, to have a dopant profile characterized as corresponding to an outer or surface portion of the CBL with a higher concentration of the p-type dopant material (e.g., than a concentration of the p-type dopant material in an inner portion of the CBL).

Further, in specific instances the method may be used to form a field-effect transistor that includes each of the CBL, the first material layer and the other material layer.

The steps of the manufacturing may also include or involve diffusion. For example, such a diffusion step may include the p-type dopant material being diffused to create the CBL doping profile with the p-type dopant material being activated without recovered crystallinity, wherein the CBL doping profile has a fixed distribution of the p-type dopant material upon completion of the diffusion step. As another example, such a diffusion step may include the p-type dopant material being diffused to create the CBL doping profile without heating or an annealing the CBL at a temperature necessary to recover crystallinity in the CBL. Preferably, this methodology does not include an annealing step, for the CBL, above a temperature needed for crystal recovery and dopant activation; and the step of forming the CBL does not include use of a high-energy ion-implanter.

In further specific example embodiment, the semiconductor device which includes the CBL is not implemented as a transistor but rather as a pn-junction semiconductor device, for example, corresponding to an optical device (e.g., solar cell or LED (light-emitting diode), another type of diode, or another type of semiconductor device. In such specific examples, the above apparatuses (e.g., semiconductor devices) and/or their related method of use or manufacture need not have a second or other material layer, with the CBL sandwiched as such. In these specific examples, the device may be characterized with regards to a CBL and an adjacent semiconductor (first material) layer. The CBL may have a surface portion along a surface portion of the CBL adjacent (e.g., immediately adjacent) to the first material layer. The first material layer is formed to include n-type dopant material that is activated with recovered crystallinity, and the CBL is formed to include a p-type dopant material, located within the CBL and activated without recovered crystallinity, to have a dopant profile characterized as corresponding to an outer or surface portion of the CBL with a higher concentration of the p-type dopant material. Again, other aspects disclosed herein (e.g., in connection with a transistor including such a CBL) may also be combined with and applicable to the above-characterized pn-junction semiconductor device.

More specific exemplary methods may include a processing step involving spin-on-glass (SOG) to form the current blocking layer, and/or processing the first material layer via an implantation and activation process, and causing a part of the surface portion of the CBL to include at least one of Silicon and n-type dopants. Such methods may alternatively or further include a surface-channeling doping step, in which the surface is doped to affect a threshold voltage and on-current of the transistor.

In connection with methods of use and also manufacture of such devices, the electrical behavior of the CBL may be tested for confirmation of expected or designed behavior. This may involve operating or testing the CBL and confirming that the dopant profile beyond a part which includes a part of the surface portion having at least one of Silicon and n-type dopants, is unchanged during the processing of the first material layer.

In yet other specific aspects, the present disclosure concerns a vertical gallium oxide (Ga₂O₃) transistor consisting of a magnesium (Mg) diffusion-based current blocking layer (CBL) is demonstrated. The transistor is made on a conductive Ga₂O₃ substrate with a lightly doped homo-epitaxial layer on top. The magnesium dopant source is first deposited and patterned on the sample. A controlled thermal diffusion process is utilized to form the Mg-doped regions as the CBL inside the sample, followed by the doping of the source contact region by ion implantation. The source electrodes are then deposited on top of the source doped region. A thin dielectric layer is deposited over the surface as the gate oxide. The gate electrode is aligned with the gate region on top of the dielectric layer.

Further exemplary aspects of the present disclosure, which may be related to the above aspects, concern the use of a p-type dopant, such as Mg, because of attributes including one of the lowest formation and activation energy among all possible metallic elements and because Mg can effectively capture electrons and reduce conductivity in n-type Ga₂O₃, thus capable of serving as deep electron traps at the least if not a p-type dopant. As noted previously, however, the demonstration of Ga₂O₃ vertical transistor with Mg-doped current blocking layer (CBL) by ion-implantation has shown weak gate modulation with almost no blocking behavior, and in certain contexts this is a significant problem.

According to certain aspects, the present disclosure takes advantage of the high diffusivity of Mg in Ga₂O₃, so as to render it possible to dope Ga₂O₃ with Mg diffusion technique for a sufficient depth for vertical power device applications (noteworthy as there appears to be little if any research of vertical diffused transistor reported on wide-bandgap (WBG) materials). In the very mature silicon carbide (SiC) field, this is likely due to the low diffusivity of dopants in SiC at a relatively high temperature, which may make render diffusion doping as being deemed impossible. However, for Ga₂O₃ as in certain aspects of the present disclosure, the situation is different and diffusion doping of Mg is worthwhile. As examples, such device according to the present disclosure facilitates in the delivery of significantly-improved efficiency, higher-power density, smaller size, and much lower cost than currently available technology, such as the silicon and silicon carbide devices used in Tesla electric cars and DC fast charging stations.

In more specific examples according to the present disclosure, a Ga₂O₃ vertical transistor is made or provided so as to include a diffused barrier transistor (e.g., VDBFET), with selective Mg diffusion doping technique being developed to form the CBL. In one example, Mg-doped spin-on-glass (Mg-SOG) is chosen and a furnace thermal diffusion technique is used to accomplish this because they are the most readily available sources and techniques. Compared to ion implantation doping, the diffusion doping process is non-invasive which leaves no crystal damage thus requiring no annealing afterward. This is effectively a one-step doping process that ensures that the profile achieved at the end of diffusion doping is fixed permanently as long as the latter processing temperature is kept below the diffusion temperature. Furthermore, the doping profile from diffusion doping is more favorable and ideal as it usually creates a near box profile with a high concentration at the surface, wherein the near box is characterized as having a flat concentration profile for more than 70% of the doped region with the tail decays to below 1e14/cm³ (or detection limit, whichever is lower) within 1 μm distance from the start of the tail. For implantation doping, the highest doping location is somewhere in the middle and providing a mountain peak-like profile. This results in a normally off operation without the need of any additional channel doping subsequently. Further, this simplifies the fabrication process for enhancement mode (normally-off and with channel being open) devices if the doping concentration can be precisely controlled. Lastly, the use of Mg-SOG and thermal diffusion is easier and cheaper without the need for a high-energy ion-implanter. All the above advantages indicate that the selective diffusion doping technique is especially useful for Ga₂O₃ vertical power devices. Moreover, an effective Mg-doped layer can be used as edge terminations in a wide variety of devices. As used herein, near box profile refers to the highest doping location being at the surface, and the doping level either stays constant or decreases as the dopant goes deeper, and high doping concentration is typically in the range of 1e20˜1e21/cm³. Diffusion doping can go as deep as 10 um or even deeper (>10 um), whereas implantation can only penetrate ˜1 um, and any implantation >1.5 um is extremely challenging.

According to the present disclosure, the successful demonstration of a vertical FET using exemplary aspects according to the present disclosure proves its feasibility and its viable impact on the development of Ga₂O₃ electronics research and real-world semiconductor applications. In certain specific implementations, real-world semiconductor applications include compact high power converters, converters that can be used in electric car on-board chargers, DC fast-charging stations, micro-grids, high power industrial equipment, power grids, etc.

More detailed proof-of-concept/experimental example embodiments are discussed below in connection with examples illustrated in various figures which, for such experiments, utilize Mg as a p-type dopant for the CBL, Mg-SOG processing to effect such doping for the CBL and Si as an adjacent material layer (e.g., n-type drift layer). However, as these figures are associated with laboratory-developed example embodiments, it will be appreciated that these figures are non-limiting with regards to the types of semiconductor structures and related materials (including dopant types and chemistry makeups). For example, other specific exemplary embodiments (not illustrated herein) according to the present disclosure do not require Mg as a p-type CBL dopant and/or any SOG processing. In certain specific examples: instead of Mg or in addition thereto, at least one of Zn and/or N (or another p-type carrier which behaves adequately according to device specifications whether in transistor-based or other type of semiconductor device benefiting from a CBL layer) may be used as the p-type dopant(s); and instead of SOG or in addition thereto, another diffusion-doping technique (e.g., which may or may not include gas-diffusion) may be used.

In yet other specific examples, aspects are directed to addressing one or more problems as be recognized from the foregoing and/or following discussion which involve more detailed proof-of-concept and/or experimental embodiments based on experiments with an Mg-SOG selective doping for current-blocking-layer. These experiments are discussed as follows.

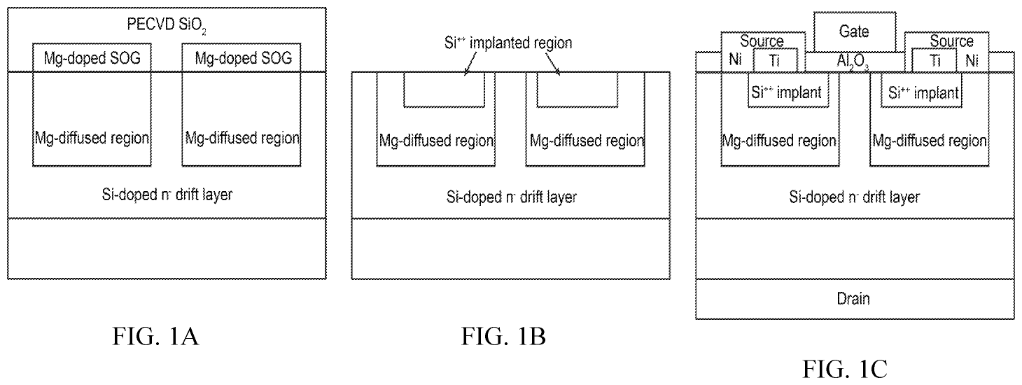

In the conventional thermal diffusion doping technology, a hard mask usually consists of dielectric which is formed on top of the target substrate first. The hard mask is then patterned or etched to open windows where the doping is desired. The dopant source in the forms of vapor or sol-gel layers is then exposed to the sample. However, in connection with this experimentation and according to the present disclosure the inventors discovered that Mg diffuses significantly in almost all materials usually used as the hard mask for the high temperature drive-in diffusion. This makes masking engineering extremely challenging. Therefore, the process may be modified to eliminate the need for a mask layer. Using the example SOG doping technique, in connection with this experimentation and according to the present disclosure, a blanket layer of the Mg-doped SOG is first deposited onto the substrate. This SOG layer is then patterned with conventional photolithography followed by an HF-based wet-etch to remove the SOG where the doping is not desired. This leaves a patterned Mg SOG layer where SOG is located exactly at the desired doping region, achieving the goal of selective doping. To isolate the thermal diffusion process from the outside environments and to relieve the thermal stress build-up in the SOG film during the high temperature diffusion process, a PECVD SiO₂ layer of approximately 1 μm is deposited on top as a capping layer, and the schematic at this stage is shown in FIG. 1A (PECVD referring to plasma-enhanced chemical vapor deposition).

More specifically, by way of FIG. 1A along with FIGS. 1B and 1C, exemplary fabrication process steps are depicted for forming an exemplary transistor, in this example, a Ga₂O₃ VDBFET in accordance with the present disclosure. Via a cross-section schematic view showing exemplary fabrication process steps of an exemplary transistor (e.g., Ga₂O₃ VDBFET), FIG. 1A shows the device during the process after the drive-in diffusion of Mg dopants from SOG, wherein the SOG is patterned by HF etch and covered with a blanket PECVD SiO2 layer prior to diffusion. FIG. 1B shows the device during the process after the silicon ion-implantation and activation for source region, the n+-CBL-n− structure is formed. Finally, FIG. 1C shows the final fabricated device.

In the above example, the Ga₂O₃ wafer used in this experiment consists of a 10 μm halide-vapor-phase-epitaxy (HVPE) grown Si-doped n layer with a carrier density around 2×10¹⁶ cm⁻³ on top of an Sn doped conductive substrate. Due to the typically-high temperature(s) used for diffusion doping, this process is performed relatively early in the process. The Mg-SOG is spin-coated onto the wafer and bake on a hotplate to drive out the solvent and form an amorphous glass layer with a high concentration of Mg. The selective doping diffusion stack shown in FIG. 1A is then formed with the above-mentioned method. Due to the high concentration (>4×10²¹/cm³) of Mg inside the SOG layer, the layer can be considered as an infinite dopant source for diffusion purposes. One of the more important parameters in the thermal diffusion process is the diffusion temperature. A series of Mg diffusion doping experiments were carried out with various temperatures and durations to determine the optimal conditions for device fabrication.

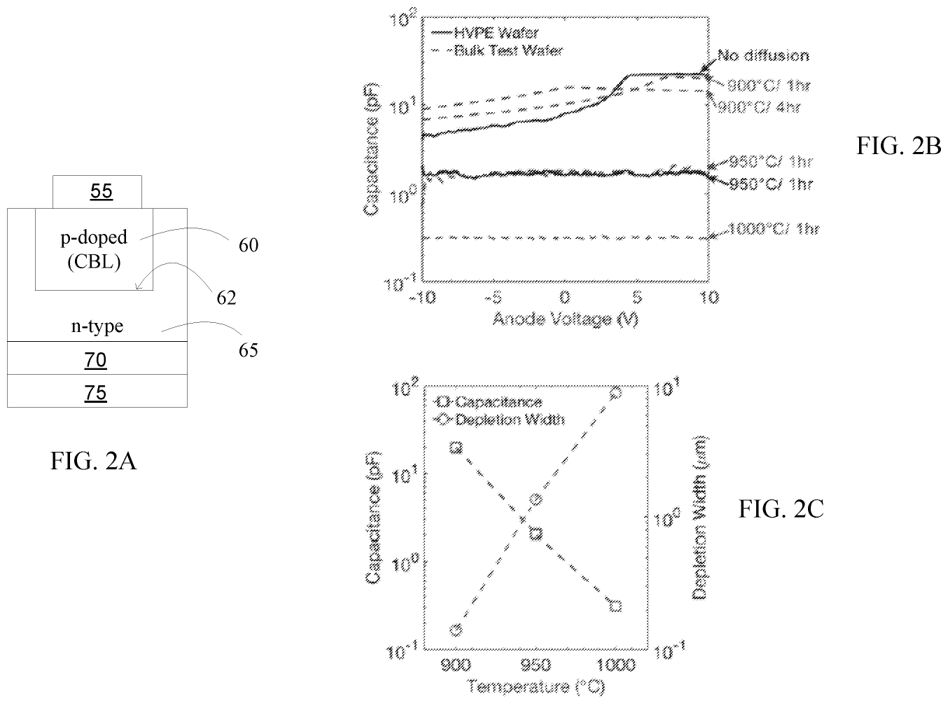

In connection with a particular example according to the present disclosure, reference may be made to FIG. 2A which depicts a cross-section schematic of an experimental device constructed in a manner consistent with the above aspects. The device of FIG. 2A includes a pn junction device (e.g., as in a diode or FET, and/or as part of or referring to any of a variety of semiconductor devices) based on regions (aka layers) 55 and 60. The region 60 may be considered the CBL and it is p-type doped (via a p-type dopant material which is activated without recovered crystallinity), and the region 55 may be considered an electrode (e.g., positively charged for electrons moving from the region 60). The region 60 may be located between the region 55 and a region 65 having n-type dopant material that is activated with recovered crystallinity. On the other side of the n-type region 65, there may also be a conductive substrate region 70 (e.g., n-type) and another region (e.g., region 75) may another electrode (e.g., negatively charged).

As should be apparent from a more generalized perspective, the device(s) of each of FIGS. 1A, 1B and IC correspond to at least the part of FIG. 2A which includes the CBL having the p-type dopant material and activated without recovered crystallinity, and which includes a material layer having n-type dopant material that is activated with recovered crystallinity. This follows as each of these figures FIGS. 1A, 1B, 1C and 2A shows a similarly-constructed region (CBL) 60 and region 65. More specifically and for the purposes of clarity, in each of FIGS. 1A, 1B, IC and 2A, the semiconductor device includes an n-type region (e.g., 65 of FIG. 2A) and a CBL (e.g., 60 of FIG. 2A) with a surface portion 62 which is located (e.g., along a planar direction of the surface portion 62) adjacent an interface region between these two regions (e.g., 60 and 65 of FIG. 2A). In other embodiments of the present disclosure, the n-type region (e.g., 65 of FIG. 2A) may be considered a part of the semiconductor device corresponding to a first (e.g., semiconductor-material-based, aka material) layer having n-type dopant material that is activated with recovered crystallinity, wherein the p-type dopant material located within the CBL (activated without recovered crystallinity) has a dopant profile characterized as corresponding to an outer or surface portion of the CBL with a higher concentration of the p-type dopant material (e.g., higher than a concentration of the p-type dopant material in an inner portion of the CBL).

In a more specific experimental embodiment corresponding to the semiconductor device depicted in FIG. 2A may have the layers 55, 60, 65, 70 and 75 implemented to form a diode. In this example, the layer 55 may be an anode, the layer 60 may be an Mg-doped region (e.g., with a dimension w_{d} extending from the lower surface of the anode layer 55 to the lower surface of the Mg-doped region), the layer 65 may be a Si-doped n-type drift layer, the layer 70 may be an Sn-doped conductive substrate, and the layer 75 may be a cathode. In yet a more particular example implementing a diode-type semiconductor device as in FIG. 2A, the device may be implemented to form a circular Ni/Au stack with a diameter of 200 μm. For example, implementing the semiconductor device as a Schottky barrier diode, FIG. 2B depicts capacitance-voltage characteristics of the diode and with an Mg-doped CBL region with various diffusion doping conditions, in accordance with the present disclosure. Data from the actual HVPE device wafer is shown in solid lines, equivalent data collected from a test bulk wafer is shown in dashed lines, and the annealing temperatures and durations are listed on the right side of the plot. FIG. 2C depicts the dependence of capacitance and depletion width on the annealing temperature, in accordance with the present disclosure. The three capacitance values are taken from the bulk test wafer data at 10 V anode voltage with the following conditions: 900° C./1 hr, 950° C./1 hr, and 1000° C./1 hr.

With the capacitance-voltage (CV) test structure and data of the HVPE wafer are shown in FIG. 2A and FIG. 2B, consider or assume an ideal parallel plate capacitor model. In this context, the depletion depth of the Mg-doped region can be calculated. In addition, a few equivalent tests are performed on a Ga₂O₃ bulk wafer with unintentional doping of ˜3×10¹⁷ cm⁻³. The lateral CV measurement technique and depletion width formula is detailed in Ref. 30 (Appendix A). It is shown that 950° C./1 hr is an optimal diffusion condition, as this gives a depletion depth (Wd) of about 1.6 μm. Below 900° C., the diffusion of Mg in Ga₂O₃ is negligible, while above 1000° C., the Mg diffuses too deeply into the substrate. These observations agree well with the reported diffusivity of Mg inside Ga₂O₃. Finally, the drive-in diffusion for the VDBFET is carried out at 950° C. for 1 hour in an N₂ ambient at atmospheric pressure. The doping oxide stack is stripped clean by an HF dip afterward.

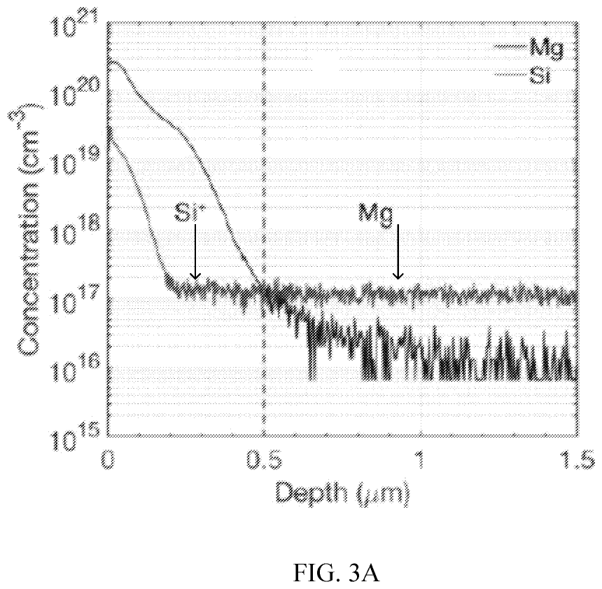

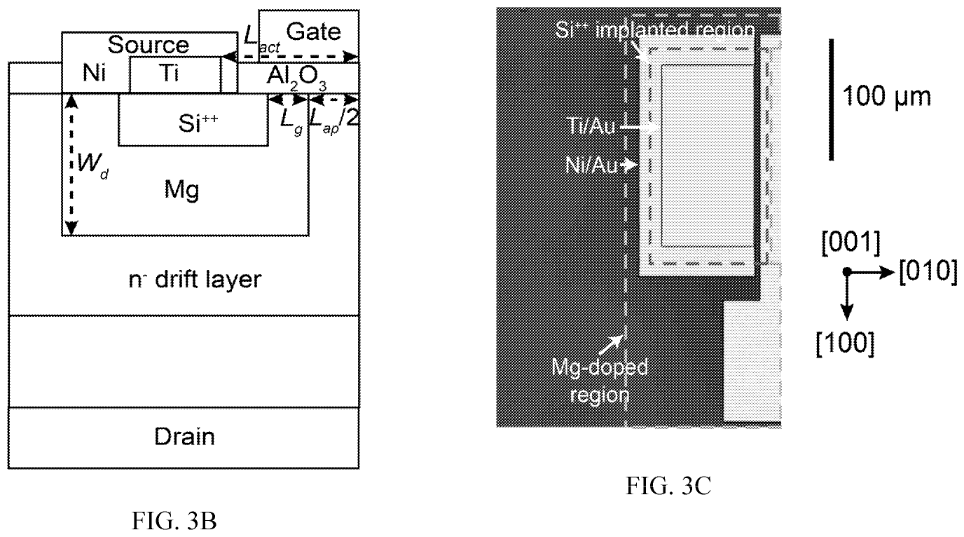

Discussion now turns to exemplary aspects of the present disclosure which may involve an enhancement mode device (e.g., Ga₂O₃ VDBFET) in which the device is normally in an offstate while the device's channel is open (not conducting). After the selective Mg diffusion doping, the Si⁺⁺ ion-implantation is performed to form the source and drain contact region as shown in FIG. 1B. The activation of Si dopants is performed at 900° C. to avoid altering the Mg dopant profile while maintaining a decent activation efficiency. The SIMS depth profile of the Mg and Si doping in the implanted region is shown in FIGS. 3A, 3B and 3C.

More specifically, FIGS. 3A, 3B and 3C show a certain exemplary device and its performance aspects according to the present disclosure. FIG. 3A depict aspects of a SIMS depth profile of Si and Mg in a related n+ implanted region of a device as shown in FIG. 3B. In FIG. 3B, the surface region from 0 to 0.5 μm is dominated by the implanted Si dopant making it a highly conductive n layer, and the implanted silicon is unlikely to penetrate beyond 1 μm depth, thus leaving the Mg-doped region here unaffected. FIG. 3C depicts an optical image of the measuring device, wherein different doping regions are indicated with dashed lines.

The profile shows the presence of Mg inside the device after diffusion doping, with the dopants shown as having reached at least 1.5 um depth into the substrate with a decaying or constant concentration, and with the range(s) along the X axis and Y axis. In connection with this experiment, it is likely that both Si and Mg traces reached their detection limit beyond 1 μm depth as the data after that remains constant. The previous Mg diffusion doping experiments have shown that Mg diffusion is negligible under 900° C. This means that the dopant profile and electrical behavior of the Mg-doped region beyond the Si⁺ doped surface layer (>˜0.5 μm depth) is unchanged during the Si⁺⁺ implantation and activation process. Therefore, a sandwich structure consisting of the n+ surface layer, the Mg-doped layer, and the n− drift layer underneath is formed.

A Ti (50 nm)/Au (70 nm) contact is deposited inside the implanted n+ region as the source electrode without any contact annealing (Ti referring to titanium and Au referring to gold). The TLM (transfer-length method) measurement done in the implanted region shows a linear IV behavior with a decent contact resistance of 9.63×10⁻⁰⁵ Ω·cm². The Ni (30 nm)/Au (100 nm) contact is then deposited on top of the Ti/Au contacts to cover the Mg-doped region and hold the potential barrier between this region and the n+ region. A Ti (50 nm)/Au (100 nm) stack is deposited at the backside of the sample to form the drain electrode. A 25 nm Al₂O₃ gate oxide layer is deposited on the device by atomic layer deposition (ALD), followed by the Ti (2 nm)/Ni (30 nm)/Au (100 nm) gate metal stack deposition. The n+ implantation window is designed to be 1 μm narrower than the Mg-doped region under the gate, making the gate length of the device I_{ag}=1 μm, as indicated in FIG. 3A. The aperture length Lₐₚ is chosen to be 24 μm for this experiment.

In connection with certain exemplary processes according to the present disclosure, annealing at temperatures less than or below 900° C. after the diffusion doping is preferred (e.g., 900° C. annealing may be used later in the process for the Si implantation activation as described above). If annealing is done at more than 950° C., the CBL will likely be disrupted, and the device will not block, thereby rendering the CBL ineffective.

The representative DC-IV characteristics and optical image of the fabricated VDBFET are shown in FIGS. 4A, 4B and 4C. The output characteristic was measured with V_{g} sweeping from 0 to 12 V with an increment of 2V. The fabricated device showed a maximum on-current of 0.15 kA/cm². The current density is normalized with the area of W_{c}×(L_{act}+Lₜ), where W_{c}=150 μm is the Ti/Au contact width, L_{act}=23 μm is the active length indicated in FIG. 3B, and Lₜ=7.3 μm is the current transfer length measured by TLM.

In connection with the device discussed above with FIGS. 3A, 3B and 3C, FIGS. 4A, 4C and 4C depict DC-IV characteristics of an example fabricated VDBFET, in accordance with the present disclosure, with L_{g}=1 μm (gate length). FIG. 4A shows representative output (V_{ds}-I_{d}) characteristics of the device. FIG. 4B shows transfer (V_{gs}-I_{d}) characteristic of the device at V_{d}=10 V in linear scale, and FIG. 4C shows transfer (V_{gs}-I_{d}) characteristic of the device at V_{d}=10 V in semi-log scale.

The measured raw value is shown on the right axis in FIG. 4A for reference. In theory, due to the nature of Mg deep traps, the electrons in the gate region (L_{g}) are completely neutralized at zero voltage, so that the device is normally off. For this example device, a turn-on voltage of ˜7V is required (according to FIG. 4B) to invert the channel. A decent on/off ratio of 10⁸ is measured in the transistor, indicating excellent gate modulation. However, the breakdown voltage (V_{br}), shown in FIG. 5A is lower (e.g., measured in certain experiments to be merely 72 V at V_{g}=0 V). More specifically, FIG. 5A depicts three terminal breakdown characteristics of the device of FIGS. 4A, 4B and 4C. The depicted drain leakage current exceeds 100 μA at 72 V. Further decreasing V_{g} did not help to achieve higher V_{br}.

FIG. 5B depicts an example pn semiconductor device (e.g., as a diode might be constructed) also including a CBL according to the present disclosure. The device of FIG. 5B may be used as a test device to measure performance and behavior of one or more of the example embodiments including similarly-constructed junctions (e.g., with similar processing steps and material-layer chemistries). The device of FIG. 5B also corresponds to one of various pn junction examples which may be used in a semiconductor device which is a diode or not a transistor of the types shown in the previous figures.

Nevertheless, when compared to the last publication of a vertical transistor with a Mg-doped CBL, where the switching (modulation) is extremely weak which gives an on/off ratio of less than 1 order of magnitude, the improvement is significant. The improvement in the blocking capability here indicates that the doping density and profile of the Mg CBL play an important role in the blocking behavior. Therefore, one may reasonably conclude that a higher Mg doping in the CBL results in stronger blocking. Conversely, the Mg-doped CBL in the above example embodiments may not hold against the increasing V_{d} due to a lower-than-expected Mg doping as shown in FIG. 3A. This exemplary prototype device is fabricated with a minimal design and the least steps to serve as a proof of concept. Further improvements can be expected by further optimizations.

Accordingly, according to certain aspects and examples as above, a planar Ga₂O₃ VDBFET is disclosed with a certain Mg-diffusion-doped CBL, and with reported showing that it is possible to use thermally diffused Mg-doped region as CBL in vertical Ga₂O₃ transistors. This may be used to provide a baseline process flow for the fabrication of the future Ga₂O₃ VDB-type FETs (VDBFETs). In one proof-of-concept example, the transistor showed enhancement mode operation with a maximum on-current of 0.15 kA/cm² and a current on/off ratio of 10⁸. The breakdown voltage measured at V_{g}=0V is 72 V, indicates a large space for improvement in the V_{br}. These results have shown that the Mg-SOG thermal diffusion technique and the Ga₂O₃ transistor platform based on it have proven to be viable paths towards high-performance Ga₂O₃ vertical transistor and will be valuable additions to particular Ga₂O₃ device research efforts.

Also according to the present disclosure and also in connection with the above experiments, discussion now turns to methods used in fabrication of such above-described devices. The Ga₂O₃ HVPE wafer is produced by Novel Crystal Technology, Inc. The Mg-doped SOG used in this experiment is manufactured by Desert Silicon, Inc. with an Mg concentration of 4×10²¹/cm³. After spin-coating at 3000 rpm followed by hot-plate baking at 250° C. for 10 minutes, the doped glass layer has a thickness around 180 nm. Conventional photolithography (using Heidelberg MLA 150 direct laser write tool) is then used to pattern the SOG layer coupled with an HF (50:1) etch. The 1 μm PECVD SiO₂ layer is deposited by a PlasmaTherm shuttlelock PECVD system. The Mg drive-in annealing is performed with a Tylan horizontal infrared furnace with a slow (˜1 hour) ramp to 950° C. and a hold time of 1 hour for the thermal diffusion. The diffusion is performed under atmospheric pressure with a slow pull and push loading and a nitrogen flow rate of 3 sccm. The oxide stack is then striped with an HF (6:1) dip. A triple Si implantation with dose and energy of 1.03×10¹⁴ cm⁻²/30 keV, 1.77×10¹⁴ cm⁻²/60 keV, and 3.04×10¹⁴ cm⁻²/120 keV is used for source contact doping. The beam is tilted 7° with respect to normal to avoid channeling, and the implantation is performed at room temperature with a thick layer of thermally cured photoresist as mask which is stripped in remover 1165 afterwards. The activation annealing is carried out at 900° C. for 15 minutes in an Allwin 610 rapid thermal process system under a nitrogen flow of 10 sccm. The source, drain, and gate metallization is done by the AJA e-beam evaporator and standard lift-off process. The gate oxide is deposited by a Fiji F202 system from Cambridge Nanotech. And the oxide thickness is verified with a Woollam M-2000 spectroscopic ellipsometer.

It is recognized and appreciated that as specific examples, the above-characterized figures and discussion are provided to help illustrate certain aspects (and advantages in some instances) which may be used in the manufacture of such structures and devices. These structures and devices include the exemplary structures and devices described in connection with each of the figures as well as other devices, as each such described embodiment has one or more related aspects which may be modified and/or combined with the other such devices and examples as described hereinabove may also be found in the Appendices of the above-referenced Provisional Application.

The skilled artisan would also recognize various terminology as used in the present disclosure by way of their plain meaning. As examples, the Specification may describe and/or illustrates aspects useful for implementing the examples by way of various semiconductor materials and/or circuits which may be illustrated as or using terms such as layers, blocks, modules, device, system, unit, controller, and/or other circuit-type depictions. Also, in connection with such descriptions, the term “source” may refer to source and/or drain interchangeably in the case of a transistor structure. Such semiconductor and/or semiconductive materials (including portions of semiconductor structure) and circuit elements and/or related circuitry may be used together with other elements to exemplify how certain examples may be carried out in the form or structures, steps, functions, operations, activities, etc. In other instances, “plane” is used merely to provide antecedent for an orientation of a surface (e.g., surface portion of the CBL), “surface” is used for reference purposes regarding an outer portion of CBL relative to an inner portion, and ‘layer” may include multiple (sub) layers and/or be formed via different steps and along different directions (e.g., as in FIGS. 1A-1C and others). It will also be appreciated that illustrations in the figures and terms used herein (e.g., “layer”, “surface”, etc.), unless otherwise indicated, are not intended to be limiting with respect to shapes, sizes, length (e.g., surface-layer length), etc. For example, in certain specific embodiments according to the present disclosure, one or more contemplated CBL-based devices may have a relatively-small portion surface portion of a CBL which is part of a curved outer part of the CBL. Further (and especially in connection with the discussion herein of the laboratory-related detailed experimental examples), unless otherwise indicated ranges (of any, and all metrics) are merely exemplary of “approximate ranges” wherein this term may be understood to vary the bound(s) of the range (e.g., using improved and/or degraded material-or circuit-based design parameters) by a degree of anywhere from 10-to-20 percent (or in some instances) from 5-35 percent, and, in the context of comparison to an improvement over a previously-reported effort, by a degree of improvement of 20 percent or greater (such previously-reported effort(s) may be identified by referencing the citations listed as part of the underlying U.S. Provisional Application).

It would also be appreciated that terms to exemplify orientation, such as upper/lower, left/right, top/bottom and above/below, may be used herein to refer to relative positions of elements as shown in the figures. It should be understood that the terminology is used for notational convenience only and that in actual use the disclosed structures may be oriented different from the orientation shown in the figures. Thus, the terms should not be construed in a limiting manner.

Based upon the above discussion and illustrations, those skilled in the art will readily recognize that various modifications and changes may be made to the various embodiments without strictly following the exemplary embodiments and applications illustrated and described herein. For example, methods as exemplified in the Figures may involve steps carried out in various orders, with one or more aspects of the embodiments herein retained, or may involve fewer or more steps. Such modifications do not depart from the true spirit and scope of various aspects of the disclosure, including aspects set forth in the claims.

1. A circuit comprising:
a semiconductor device including a first material layer having n-type dopant material that is activated with recovered crystallinity, and including a current-blocking layer (CBL) having a surface portion which is located adjacent the first material layer; and
a p-type dopant material, located within the CBL and activated without recovered crystallinity, having a dopant profile characterized as corresponding to an outer or surface portion of the CBL with a higher concentration of the p-type dopant material than a concentration of the p-type dopant material in an inner portion of the CBL.

2. The circuit of claim 1, wherein the semiconductor device is a field effect GaO-type transistor, or the p-type dopant material includes Magnesium (Mg).

3. (canceled)

4. The circuit of claim 1, wherein a part of the surface portion of the CBL includes Silicon and/or n-type dopants immediately adjacent the first material layer.

5. The circuit of claim 1, wherein the current blocking layer forms part of a Ga₂O₃ vertical diffused barrier field-effect-transistor (VDBFET).

6. The circuit of claim 1, wherein the dopant profile is further characterized by having a near-box with a linear upper part corresponding to a highest level of dopant concentration at the surface portion and with linearly-sloped sides.

7. The circuit of claim 1, further including an electric power converter configured to convert an input power source to a power source for a load through the use of signal modulation, and wherein the semiconductor device is a field-effect transistor (FET), including a channel, to switch or otherwise facilitate driving one or more signals as part of the signal modulation, wherein the dopant profile is to facilitate an operation which corresponds to the FET being in a normally-off state of operation while the channel is open.

8. The circuit of claim 1, further including an ultra-wide-bandgap (UWBG) semiconductor-beta-gallium oxide (β-Ga₂O₃) power-sourcing circuit of which the semiconductor device forms a part.

9. The circuit of claim 1, wherein the semiconductor device is a diffused-barrier-field-effect transistor which exhibits an on-off operation-switching ratio which is greater than 10⁵ (e.g., approaching or exceeding 10⁸).

10. A method comprising
operating a semiconductor device including a first material layer having n-type dopant material that is activated with recovered crystallinity and including a middle current-blocking layer (CBL) having a surface portion which is located adjacent to the first material layer; and
using the CBL in at least one of multiple states of operating the semiconductor device to block current via a p-type dopant material that is located within the CBL and activated without recovered crystallinity, and that has a dopant profile characterized as corresponding to an outer or surface portion of the CBL with a higher concentration of the p-type dopant material than a concentration of the p-type dopant material in an inner portion of the CBL

11. (canceled)

12. The method of claim 10, wherein said at least one of multiple states includes a normal-off state during which the CBL blocks current.

13. The method of claim 10, further including operating the semiconductor device as a transistor with the CBL being used to facilitate signal-edge terminations for signals coupled to and effected by the transistor transitioning through one or more of the multiple states.

14. The method of claim 10, wherein the semiconductor device is used as a transistor to facilitate switching and/or modulation of one or more signals as part of the switching or modulation in an electric power converter, and while using the electric power converter to convert an input power source to a power source for a load through the use of the switching or modulation.

15. A method comprising:
forming a current-blocking layer (CBL) having a surface portion located adjacent a first material layer which includes n-type dopant material that is activated with recovered crystallinity, and the CBL includes a p-type dopant material, located within the CBL and activated without recovered crystallinity, having a dopant profile characterized as corresponding to an outer or surface portion of the CBL with a higher concentration of the p-type dopant material than a concentration of the p-type dopant material in an inner portion of the CBL; and
forming a semiconductor device that includes each of the CBL and the first material layer.

16. The method of claim 15, further including a diffusion step in which the p-type dopant material is diffused to create the CBL doping profile with the p-type dopant material being activated without recovered crystallinity, wherein the CBL doping profile has a fixed distribution of the p-type dopant material upon completion of the diffusion step.

17. The method of claim 15, further including diffusing the p-type dopant material to create the CBL doping profile without heating or an annealing the CBL at a temperature necessary to recover crystallinity in the CBL.

18. The method of claim 15, further including a processing step involving spin-on-glass (SOG) to form the current blocking layer.

19. The method of claim 15, further including processing the first material layer via an implantation and activation process, and causing a part of the surface portion of the CBL to include at least one of Silicon and n-type dopants.

20. The method of claim 15, wherein forming a semiconductor device includes forming a field-effect transistor with the CBL located between the first material layer and a second material, wherein the second material layer is biased as an n-type material.

21. (canceled)

22. The method of claim 15, further including operating or testing electrical behavior of the CBL and confirming that the dopant profile, beyond a part which includes a part of the surface portion having at least one of Silicon and n-type dopants, is unchanged during the processing of the first material layer and including a surface channeling doping step, in which the surface is doped to affect a threshold voltage and on-current of the semiconductor device.

23. The method of claim 15, wherein the steps of forming do not include an annealing step, for the CBL, above a temperature needed for crystal recovery and dopant activation, and the step of forming the CBL does not include use of a high-energy ion-implanter.

24. (canceled)
